(19) United States
(12) Patent Application Publication
(10) Pub. No.: US 2006/0124928 A1
(43) Pub. Date: Jun. 15, 2006

(54) Integrated circuit disabling

(75) Inventor: Fabrice Marinet, Chateauneuf Le Rouge (FR)

Correspondence Address: STMicroelectronics Inc.;c/o WOLF, GREENFIELD & SACKS, PC, Federal Reserve Plaza, 600 Atlantic Avenue, BOSTON, MA, 02210-2206, US

(73) Assignee: STMicroelectronics S.A., Montrouge (FR)

(21) Appl. No.: 11/302,620

(22) Filed: Dec. 14, 2005

(30) Foreign Application Priority Data
Dec. 14, 2004 (FR) 04/52964

(51) Int. Cl. H01L 23/58

(52) U.S. Cl. 257/48

(57) ABSTRACT

A method and a circuit for protecting at least one element of an integrated circuit, including conditioning the operation of the element to be protected to the state of a signal conditioned by an irreversibly programmable element, the state of which is set during a probe test of the integrated circuit.

### BACKGROUND OF THE INVENTION

1. Field of the Invention

The present invention generally relates to integrated circuits and more specifically to the protection of information contained in integrated circuit chips rejected as a result of circuit tests.

The present invention more specifically applies to circuits containing a microcontroller.

2. Discussion of the Related Art

The manufacturing of integrated circuits is performed by wafers containing several circuits. Once manufactured, the wafers are tested, that is, the different circuits undergo a series of functional tests by means of probe board type test tools. Such tests enable eliminating defective systems before the packaging steps.

In practice, the circuits are tested one after the other or in groups and those which are identified as defective are marked (generally, by means of an ink drop). Then, once the wafer has been sawn to individualize the circuits, the marking is optically detected to reject defective circuits. In fact, these circuits are left on a support tape used for the sawing from which only the correct circuits are picked to be packaged.

A problem appears when the integrated circuits contain, by manufacturing, information considered as critical or that must remain secret. Such information may be specific secret keys or functions (calculation algorithms) which are set during manufacturing (for example, by a mask).

The secret elements are present both in valid circuits and in defective circuits. A problem is then posed, as to the destination of the defective circuits that must be destroyed to avoid that the secrets they contain are discovered by unscrupulous users (hackers) collecting the defective circuits. Indeed, the defects of a circuit may be sufficient to prevent a proper operation without making access to the critical information that the circuit contains impossible (for example, the reading from the ROM areas in which secret keys have been stored during manufacturing).

This problem becomes more and more critical as the integrated circuit manufacturing locations are dispersed, which results in that the wafers and circuits often being processed by more or less controllable subcontractors. For example, sending whole wafers once tested to a subcontractor for sawing and packaging poses the problem of ensuring that “inked” circuits are effectively destroyed.

### SUMMARY OF THE INVENTION

To achieve all or part of these objects, as well as others, the present invention provides a method for protecting at least one element of an integrated circuit, comprising conditioning the operation of the element to be protected to the state of a signal conditioned by an irreversibly programmable element, the state of which is set during a probe test of the integrated circuit.

According to an embodiment of the present invention, the state of the programming element is set by application of a programming signal on a pad of the integrated circuit, which is not intended to be accessible from the outside after packaging of the circuit.

According to an embodiment of the present invention, a circuit for protecting the integrated circuit is selectable by a signal contained in a register for activating the irreversibly programmable element.

The present invention also provides an integrated circuit, comprising at least one element for protecting the access to at least one function of the circuit, the state of which is irreversibly programmed by application of a signal on a pad of the circuit during a probe test.

According to an embodiment of the present invention, said protection element comprises at least:

an irreversibly programmable element;

an element for reading the state of the programmable element; and

an element for selecting the protection circuit.

The foregoing and other objects, features, and advantages of the present invention will be discussed in detail in the following non-limiting description of specific embodiments in connection with the accompanying drawings.

### BRIEF DESCRIPTION OF THE DRAWINGS

FIG. 1 very schematically shows an example of a wafer system for testing integrated circuits in wafers, to which the present invention applies;

FIG. 2 shows an embodiment of a circuit for protecting an integrated circuit according to the present invention;

FIG. 3 partially shows an embodiment of an integrated circuit architecture according to the present invention; and

FIG. 4 is a simplified flowchart illustrating an embodiment of the integrated circuit protection method according to the present invention.

### DETAILED DESCRIPTION

The same elements have been designated with the same reference numerals in the different drawings. For clarity, only those elements which are necessary to the understanding of the present invention have been shown and will be described hereafter. In particular, the wafer test tool has not been described in detail since, the present invention is compatible with the use of conventional tools. Further, the internal structure of the integrated circuit to be protected has only been described to the extent necessary to expose exemplary embodiments.

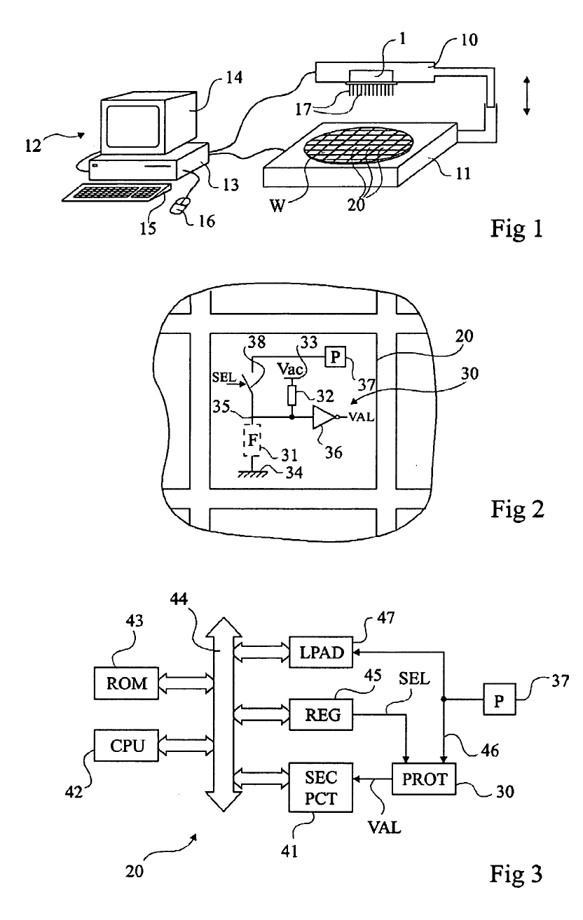

FIG. 1 schematically illustrates an example of a test system to which the present invention applies. Such a system is based on the use of a probe board 1 comprised of one or several test sites, supported by a test head 10 of a tool, on a support 11 of which is laid a wafer W of integrated circuits to be tested. Test head 10 is articulated at least vertically with respect to support 11 to be able to bring the probe board 1 close and draw it away after introduction of a new wafer W to be tested. The assembly is generally controlled by a computer element, for example, a microcomputer 12 or the like provided with a central processing unit 13, a screen 14, a keyboard 15, and a mouse 16 or other control and capture means.

The aim of the test system of FIG. 1 is to test one or several of the integrated circuits 20 formed in wafer W by means of contacts ensured by probes 17 of board 1. Probes 17 are distributed according to the pattern of contact pads (not shown in FIG. 1) of the integrated circuits to be tested. The functional tests comprise, for example, electric continuity tests, information storage tests, calculation execution tests, etc. according to the structure of integrated circuit 20 and its destination (the application or the applications for which it is intended).

After testing, the wafer W is sawn and the different integrated circuits 20 supported by the same wafer W are packaged.

To avoid having critical information (for example, keys or algorithms) integrated in circuits 20 stolen from circuits declared to be defective, the present invention provides, according to a preferred embodiment, disabling the operation of all or part of the integrated circuit by an electric control performed at the end of the probe testing.

FIG. 2 partially and very schematically illustrates an embodiment of a circuit 30 for protecting at least one secure area of an integrated circuit 20 according to the present invention. Circuit 30 is intended to provide a signal VAL conditioning the operation of a secure area of the circuit (not shown in FIG. 2) having its state conditioned by the state of a fuse or anti-fuse element 31 (F) or the like, i.e. any electrically conductive element, having a conductive state that can be irreversibly modified, independently from the circuit supply.

In the functional example of FIG. 2, the fuse element 31 is, for example, a resistive element forming with another resistive element 32 a dividing bridge between two terminals 33 and 34 to be connected to a supply voltage Vcc, their junction point 35 being connected to the input of a read element 36 (for example, an inverter) having its output providing signal VAL. According to the state of the fuse element 31, the output state of signal VAL when the circuit is submitted to a supply voltage Vcc is low or high. This signal can then be used to condition the operation of a protected area of the circuit or of the entire circuit.

The programming of the fuse element 31 at the end of the probe testing is, according to this embodiment of the present invention, performed by means of a pad 37 (P) provided in the surface of integrated circuit 20 to receive a probe 17 of the test tool, where pad 37 is not accessible from the outside of the circuit once the integrated circuit has been packaged.

Preferably, pad 37 connects point 35 via a switch 38 controlled by a signal SEL of selection of circuit 30. Selection signal SEL and switch 38 are especially used to perform parallel tests of several integrated circuits and to select, at the end of the test, those having a fusible element 31 that must be programmed or not, as will be seen hereafter.

The fuse element 31 is, preferably, an element electrically programmable under the application of a current or of a voltage on pad 37 while switch 38 is on. The programming of element 31 may result in turning off or on the electric circuit that it defines and more generally in increasing or decreasing its resistance to condition the state of output signal VAL of read element 36.

Any element with an irreversible state switching may be used. It may be a burning-out of a fuse by Joule effect, of a metal or polysilicon fuse, a destruction of a junction by thyristor effect, a modification in the resistive characteristic of an element due to a significant current, an oxide breakdown by electric field (MOS antifuse), etc.

FIG. 3 illustrates an example of a partial architecture of an integrated circuit according to an embodiment of the present invention. In a preferred embodiment, integrated circuit 20 to be protected, or having a security function 41 (SEC FCT) to be protected, comprises a central processing unit 42 (CPU) in charge of executing programs stored, for example, in a ROM 43. All the calculation elements communicate over one or several buses 44.

To implement this embodiment of the present invention, a protection circuit 30 (PROT), for example, of a type described in relation with FIG. 2, is integrated in circuit 20. In the embodiment of FIG. 3, signal SEL is provided by a register 45 (REG) programmable by microprocessor 42 and an input 46 of circuit 30, corresponding to the terminal of switch 38 (FIG. 2) having its state conditioned by signal SEL and connected to pad 37, is also connected to a circuit 47 communicating with bus 44 to receive signals originating from central processing unit 42. Circuit 47 forms the logic interface circuit (LPAD) of pad 37.

Signal VAL from circuit 30 is sent to the secure function 41 of integrated circuit 20. The action taken to block the circuit if the fuse contained in circuit 30 has been programmed (burnt out) depends on the content of circuit 41 and on the type of data (key or program) to be protected. For example, signal VAL is used to:

reset central processing unit 42 to stop its clock signal;

program to an inactive state a signal internal to circuit 41 (reset signal, clock signal, data bus directly connected to ground or address bus, etc.);

short-circuit the integrated circuit power supply;

block any communication channel, etc.

Register 45 is used as a register of activation-deactivation of the burning-out of the fuse of circuit 30. This register is preferentially controlled by central processing unit 42, which enables deactivation of the fuse burning-out during the test phase or if the circuit has been properly tested.

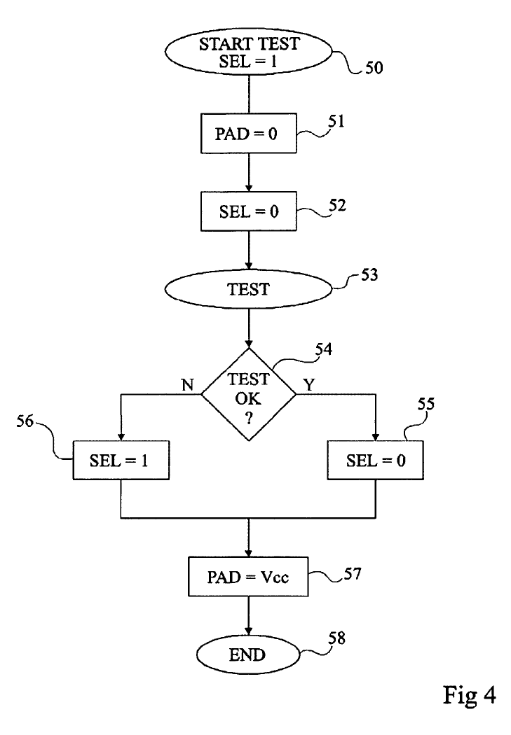

FIG. 4 is a simplified flowchart of an embodiment of the protection method according to the present invention.

At the starting of a wafer test (block 50, START TEST), the state of signal SEL of all the circuits is active (SEL=1), which is the state by default.

For all the circuits connected in parallel for a test by a probe board 1, the respective pads 37 are set (block 51, PAD=0) to an inactive state (for example, low). Central processing unit 42 of the integrated circuit or a central organ of external control of the test tool further sets (block 52, SEL=0) the selection bit conditioning the state of switch 38 to the inactive state.

The actual test can then start (block 53, TEST). This test for example is the test conventionally carried out for the considered type of circuit.

At the end of the test, whether the test results in a correct operation of the circuit is checked (block 54, TEST OK?). If yes (block 55, SEL=0), central processing unit 42 leaves bit SEL contained in register 45 (FIG. 3) in the inactive state. If test 54 is negative (defective circuit), central processing unit 42 sets (block 56, SEL=1) register 45 to the opposite state and selection signal SEL is, for the considered integrated circuit of the wafer, in an active state.

For all the circuits (nonfunctional) for which no programming is operative, signal SEL remains in the active state by default (step 52 does not succeed).

Then (block 57, PAD=Vcc), a programming voltage (for example, voltage Vdd) is applied via the probes onto pads 37 of all the circuits tested in parallel. By the respective programming of registers 45 of the different circuits, only those having signal SEL in the active state will undergo a programming of their fusible element.

The test and protection phase is then over (block 58, END).

Other test sequences may be provided. However, an advantage of the above sequence is to enable use of pad 37 in the test phase.

The circuits then undergo the usual processings. An inking of the defective circuits may be maintained to preserve the optical recognition on sawing and assembly thereof. However, all the circuits considered as defective have a completely invalid security function. Indeed, due to the fuse burning out, the application of an electric voltage on the circuit power supply will not allow it to start, signal VAL permanently and irreversibly deactivating, whatever the subsequent state of bit SEL, an element needed for the operation of the circuit or at least of its secure function.

In a preferred embodiment of the present invention, the interpretation of signal VAL or the logic wafer obtaining this signal is such that, after manufacturing, the application of a signal on pad 37 necessarily leads to a blocking of the circuit. Thus, even if a hacker succeeds in accessing the pad, though inaccessible from the outside of the integrated circuit, this does not allow him to start the circuit or the secure function. Such is the case for the embodiment described in relation with FIG. 4 where, since the state by default of signal SEL is its active state, all circuits are for the rest of their lifetime with a switch 38 in the on state. Accordingly, biasing pad 37 in the circuit lifetime burns out the fuse and blocks the circuit.

An advantage of the present invention is that protection element 30 has, due to its simplicity, little risk of being itself defective. Further, the state, active by default, of signal SEL takes part in its security. Several elements 30 may be provided in parallel to further reduce risks.

Of course, the present invention is likely to have various alterations, modifications, and improvements which will readily occur to those skilled in the art. In particular, the selection of the type of fusible element and of the action taken by the protection circuit depends on the application and is within the abilities of those skilled in the art based on the functional indications given hereabove. Further, although the present invention has been described in relation with an example in which the integrated circuits are tested in groups, the present invention also applies if the tests are performed individually for each circuit of the wafer, selection switch 38 and register 45 then being optional, where the programming of fusible element 31 can be performed by simple application of a signal on pad 37.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A method for protecting at least one element of an integrated circuit, comprising conditioning the operation of the element to be protected to a state of a signal conditioned by an irreversibly programmable element, a state of which is set during a probe test of the integrated circuit.

2. The method of claim 1, wherein the state of the programming element is set by application of a programming signal on a pad of the integrated circuit, which is not intended to be accessible from the outside after packaging of the circuit.

3. The method of claim 1, wherein a circuit for protecting the integrated circuit is selectable by a signal contained in a register for activating the irreversibly programmable element.

4. An integrated circuit, comprising at least one element for protecting access to at least one function of the circuit, a state of which is irreversibly programmed by application of a signal on a pad of the circuit during a probe test.

5. The circuit of claim 4, wherein said protection element comprises at least:
an irreversibly programmable element;
an element for reading the state of the programmable element; and
an element for selecting the protection circuit.
